(19) United States
(12) Patent Application Publication
(10) Pub. No.: US 2022/0399424 A1
(43) Pub. Date: Dec. 15, 2022

(54) PIXEL STRUCTURE, MANUFACTURING METHOD THEREOF, AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Liwang Song, Shenzhen (CN); Dongzi Gao, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/264,815

(22) PCT Filed: Dec. 18, 2020
(86) PCT No.: PCT/CN2020/137541

§ 371 Date: Jan. 30, 2021

(30) Foreign Application Priority Data
Dec. 2, 2020 (CN) 202011401376.5

(51) Int. Cl. H01L 27/32

(52) U.S. Cl. CPC H01L 27/3276; H01L 27/3246; H01L 2227/323

(57) ABSTRACT

The present disclosure discloses a pixel structure, a manufacturing method thereof, and a display device. The pixel structure includes a base layer, a first metal layer, an insulating layer, and a second metal layer. The first metal layer includes a plurality of first functional wires spaced apart from each other, and the second metal layer includes a plurality of second functional wires spaced apart from each other, wherein at least one of the second functional wire crosses at least two of the first functional wires, and at least one edge of the at least two first functional wires is defined with a space gap.

### FIELD OF INVENTION

The present disclosure relates to the field of display, in particular to a pixel structure, a manufacturing method thereof, and a display device.

### BACKGROUND OF INVENTION

Particulate matter cannot be completely eliminated during the active matrix liquid crystal display (AM-LCD) manufacturing process. Due to a presence of particulate matter, a proportion of poor circuit connections between different signal lines is relatively high. The poor circuit connections need to be repaired by a laser, but accuracy of the machine and the pixel structure design leads to the risk of failure in the repairing process and leads to the side effect of poor circuit connections. Generally, these types of poor circuit connections do not show up in the early stages of use. After a period of use, the poor circuit connections will cause clients to have poor circuits, leading to a high risk of customer complaints, affecting product quality and customer satisfaction.

The purpose of the present disclosure is to solve the technical problem of serious line disconnection or short circuiting caused by repairing of the second functional wire in the current pixel structure.

### SUMMARY OF INVENTION

In order to achieve the above object, the present disclosure provides a pixel structure, including: a base layer; a first metal layer including a plurality of first functional wires spaced apart from each other, wherein the first metal layer is arranged on a surface of one side of the base layer; a second metal layer including a plurality of second functional wires spaced apart from each other, wherein the second metal layer is insulated from and disposed above the first metal layer, wherein at least one of the second functional wires crosses at least two of the first functional wires, at least one edge of the at least two of the first functional wires is provided with a space gap for repairing the at least one of the second functional wires, and an orthographic projection of the at least one of the second functional wires on the first metal layer covers the space gap; and an insulating layer covering each of the first functional wires and filling the space gaps.

Further, one of the second functional wires crosses adjacent two of the first functional wires, and the space gaps are provided at respective edges of the adjacent two of the first functional wires.

Further, the second functional wires are voltage dividing electrode wires, and the first functional wires are common electrode wires.

Further, one of the second functional wires crosses adjacent two of the first functional wires, and the space gap is provided on an edge of one of the adjacent two of the first functional wires.

Further, the second functional wires are source wires and drain wires, and the first functional wires are gate wires.

Further, the pixel structure further includes: an active layer provided on a surface of a side of the insulating layer away from the first metal layer; a passivation layer provided on a surface of a side of the second metal layer away from the insulating layer; and a pixel definition layer provided on a surface of a side of the passivation layer away from the second metal layer.

In order to achieve the above object, the present disclosure also provides a method of manufacturing a pixel structure, including steps of: providing a base layer; providing a first metal layer on an upper surface of the base layer, wherein the first metal layer comprises a plurality of first functional wires spaced apart from each other; providing a space gap on at least one edge of the first functional wires; providing an insulating layer on an upper surface of the first metal layer and in the space gap; and providing a second metal layer on an upper surface of the insulating layer, wherein the second metal layer comprises a plurality of second functional wires spaced apart from each other, at least one of the second functional wires crosses at least two of the first functional wires, and an orthographic projection of the at least one of the second functional wires on the first metal layer covers the space gap.

Further, in the step of providing the second metal layer on the upper surface of the insulating layer includes: coating a layer of metal material on the upper surface of the insulating layer, and patterning the metal material to form the plurality of second functional wires, wherein the plurality of second functional wires comprise a source wire and a drain wire; the plurality of first functional wires comprise a gate wire; and an orthographic projection of the drain wire on the first metal layer covers the space gap.

Further, in the step of providing the second metal layer on the upper surface of the insulating layer includes: coating a layer of metal material on the upper surface of the insulating layer, and patterning the metal material to form the plurality of second functional wires, wherein the plurality of second functional wires comprise a voltage dividing electrode wire; the plurality of second functional wires comprise a common electrode wire; and the space gap is provided corresponding to an orthographic projection of the voltage dividing electrode wire on the common electrode wire.

To achieve the above objective, the present disclosure also provides a display device including the pixel structure described above.

The technical effect of the present disclosure is that a space gap is provided at the two first functional wires of the first metal layer which is crossed by the second functional wires of the second metal layer, wherein the space gap provides space for repairing the second functional wires, to prevent a short circuit between the first metal layer and the second metal layer during the repairing process, and to ensure the circuit of the pixel structure is unblocked.

### DESCRIPTION OF FIGURES

FIG. 1 is a cross-sectional view of a pixel structure according to embodiment 1 or 2 of the present disclosure.

FIG. 2 is a top view of a first metal layer according to embodiment 1 of the present disclosure.

FIG. 3 is a top view of a second metal layer according to embodiment 1 or 2 of the present disclosure.

FIG. 4 is a top view of a first metal layer according to embodiment 2 of the present disclosure.

FIG. 5 is a flowchart of a manufacturing method of the pixel structure according to embodiment 1 or 2 of the present disclosure.

### DETAILED DESCRIPTION OF PREFERRED EMBODIMENTS

The technical solutions in the embodiments of the present disclosure will be clearly and completely described below in conjunction with the figures in the embodiments of the present disclosure. Obviously, the described embodiments are only a part of the embodiments of the present disclosure, rather than all the embodiments. Based on the embodiments of the present disclosure, all other embodiments obtained by those skilled in the art without inventive steps shall fall within the protection scope of the present disclosure.

The following disclosure provides many different embodiments or embodiments for realizing different structures of the present disclosure. To simplify the disclosure of the present disclosure, the components and settings of specific embodiments are described below. Of course, they are only for examples, and are not intended to limit the present disclosure. In addition, the present disclosure may repeat reference numerals and/or reference letters in different examples. Such repetition is for the purpose of simplification and clarity, and does not indicate the relationship between the various embodiments and/or settings discussed. In addition, the present disclosure provides examples of various specific processes and materials, but those of ordinary skill in the art may be aware of the application of other processes and/or the use of other materials.

### Embodiment 1

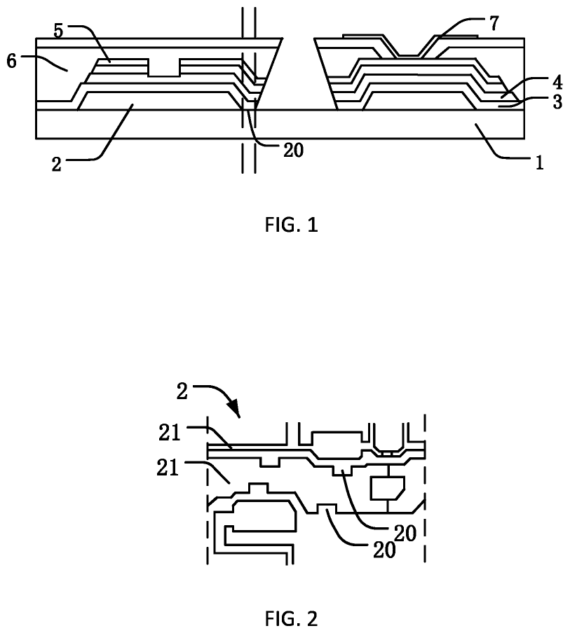

Specifically, referring to FIGS. 1 to 3, one embodiment of the present disclosure provides a pixel structure, including a base layer 1, a first metal layer 2, an insulating layer 3, an active layer 4, a second metal layer 5, a pixel definition layer 6, a pixel electrode 7, and other film layers.

The base layer 1 is a base substrate, which provides good supporting ability and is generally a glass substrate.

The first metal layer 2 is provided on an upper surface of the base layer 1. The first metal layer 2 includes a plurality of first functional wires 21 spaced apart from each other. In this embodiment, the first functional wires 21 are gate wires, wherein the gate wires can be used as scan lines.

The insulating layer 3 is provided on an upper surface of the first metal layer 2, and the material of the insulating layer 3 is an insulating material, which has a good insulating effect.

The active layer 4 is provided on an upper surface of the insulating layer 3 and is made of semiconductor material. The active layer 4 provides circuit support for the pixel structure.

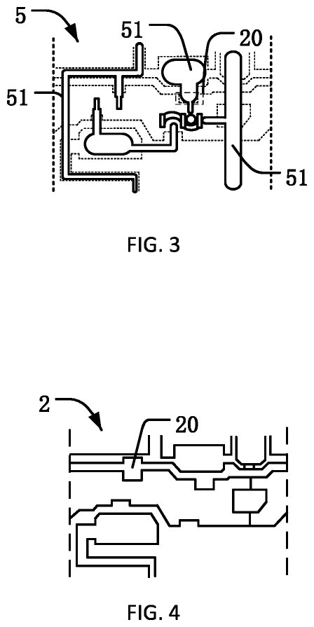

The second metal layer 5 is provided on an upper surface of the active layer 4. The second metal layer 5 includes a plurality of second functional wires 51 spaced apart from each other, wherein the second metal layer is insulated from and disposed above the first metal layer 2, wherein at least one of the second functional wires 51 crosses at least two of the first functional wires 21, at least one edge of the at least two of the first functional wires 21 is provided with a space gap 20 for repairing the at least one of the second functional wires 51, and an orthographic projection of the at least one of the second functional wires 51 on the first metal layer 2 covers the space gap 20 (as shown in FIG. 3).

In this embodiment, the second functional wires 51 includes source wires and drain wires, and an orthographic projection of the at least one of drain wires on the first metal layer 2 covers the space gap 20, and the space gap 20 is defined at the at least one edge of the first functional wires 21 of the first metal layer 2 (as shown in FIG. 2), and the space gap 20 is defined to reserve space for the subsequent repairing of the second functional wires 51.

At the same time, the space gap 20 is defined so that the insulating layer 3 can cover the first metal layer 2, so as to completely insulate the first metal layer 2 from other conductive layers. For example, the first functional wires 21 of the first metal layer 2 and the second functional wires 51 of the second metal layer 5 are completely insulated to avoid short circuiting between the first functional wires 21 of the first metal layer 2 and the second functional wires 51 of the second metal layer 5.

The pixel structure described in this embodiment may also include film layers such as a passivation layer and a flat layer, which may cover the second metal layer 5 to smooth the surface of the film layer.

The pixel definition layer 6 is arranged above the passivation layer and/or the flat layer to define the size of the light-emitting layer. The light-emitting layer can be arranged in a through hole opened on the pixel definition layer 6 to obtain a circuit structure of the pixel structure wherein the pixel structure can emit light after the circuit structure being driven.

The pixel electrode 7 is arranged in the through hole of the pixel definition layer 6 and is arranged above the light-emitting layer. The pixel electrode 7 also provides circuit support for the light-emitting of the light-emitting layer.

The technical effect of the pixel structure in this embodiment is that the space gap is provided at the edge of one of the two first functional wires 21 of the first metal layer 2 which is crossed by the second functional wires 51 of the second metal layer 5, wherein the space gap 20 provides space for repairing the second functional wires 51, to prevent short circuiting between the first metal layer 2 and the second metal layer 5 during the repairing process, and to ensure the circuit of the pixel structure is unblocked.

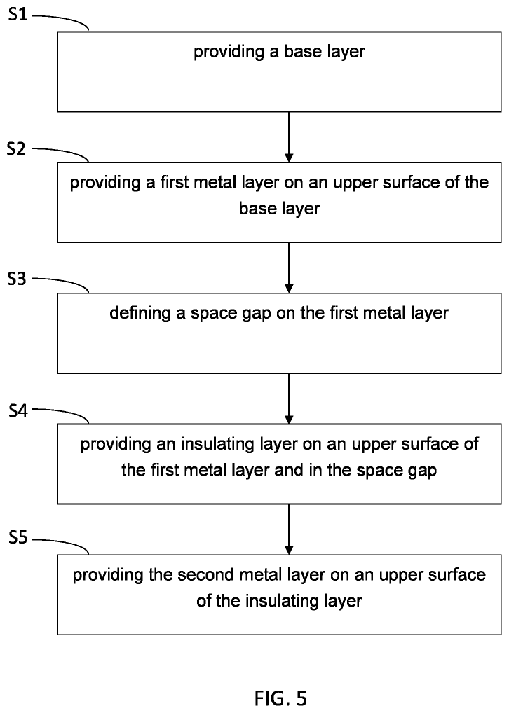

As shown in FIG. 5, this embodiment also provides a method of manufacturing the pixel structure, including steps S1 to S5.

S1: providing a base layer, wherein the base layer 1 is a base substrate, which provides good supporting ability and generally a glass substrate.

S2: providing a first metal layer 2 on an upper surface of the base layer 1. Specifically, a layer of metal material is coated on the upper surface of the base layer 1, and the metal material is patterned to form a plurality of first functional wires 21 spaced apart from each other, obtaining the first metal layer 2.

S3: performing a digging process on the first metal layer 2 to form a plurality of space gaps 20. The space gaps 20 can be formed by etching. The space gap 20 is provided at the edge of one of at least two first functional wires 21 (as shown in FIG. 2), wherein the two space gaps 20 at the edge of the two first functional wires 21 can be mutually disposed (as shown in FIG. 2).

S4: providing an insulating layer 3 on an upper surface of the first metal layer 2 and in the space gap 20. Specifically, the upper surface of the first metal layer 2 and the space gap 20 are coated with a layer of insulating material. The insulating material is an inorganic material, and the inorganic material includes silicon oxide, silicon nitride, or a multilayer film structure, which has good insulating properties.

S5: providing an active layer 4 and the second metal layer 5 on an upper surface of the insulating layer 3. Specifically, coating a layer of semiconductor material on the upper surface of the insulating layer 3 and forming the active layer 4 after channel treatment, coating a layer of metal material on the upper surface of the active layer 4, and after the patterning process, forming a plurality of second functional wires 51 spaced apart from each other, wherein at least one of the second functional wires 51 crosses at least two of the first functional wires 21, and an orthographic projection of the at least one of the second functional wires 51 on the first metal layer 2 covers the space gap 20.

In this embodiment, the first functional wires 21 are gate wires, the second functional wires 51 include source wires and drain wires, an orthographic projection of the drain wires on the first metal layer 2 cover the space gap 20, wherein the space gap 20 is defined at the edge of the first functional wires 21 in the first metal layer 2 (as shown in FIG. 2). The space gap 20 is defined to reserve space for repairing the subsequent second functional wires 51.

The technical effect of the manufacturing method of the pixel structure of this embodiment is that the space gap 20 is defined at the two first functional wires 21 of the first metal layer 2, and the space gap 20 provides space for repairing the second functional wires 51 of the second functional layer 5 to prevent short circuiting between the first metal layer 2 and the second metal layer 5 during the repairing process and to ensure that the circuit of the pixel structure is unblocked.

This embodiment can also provide a display device including the aforementioned pixel structure to avoid short circuiting between the first metal layer 2 and the second metal layer 5, and the space gap 20 provides a repairing space for disconnection at the second metal layer 5, which can prevent pixel structure from breaking, improve circuit safety performance of the display device, and ensure the yield rate of the display device.

### Embodiment 2

Specifically, please refer to FIG. 1, FIG. 3, and FIG. 4. The embodiment of the present disclosure provides a pixel structure including a base layer 1, a first metal layer 2, an insulating layer 3, a second metal layer 5, a pixel definition layer 6, a pixel electrode 7 and other film layers.

The base layer 1 is a base substrate, which provides good supporting ability and is generally a glass substrate.

The first metal layer 2 is provided on an upper surface of the base layer 1. The first metal layer 2 includes a plurality of first functional wires 21 spaced apart from each other. In this embodiment, the first functional wires 21 are common electrode wires.

The insulating layer 3 is provided on an upper surface of the first metal layer 2, and the material of the insulating layer 3 is an insulating material, which has a good insulating effect.

The second metal layer 5 is provided on an upper surface of the active layer 4. The second metal layer 5 includes a plurality of second functional wires 51 spaced apart from each other, wherein the second metal layer is insulated from and disposed above the first metal layer 2, wherein at least one of the second functional wires 51 crosses at least two of the first functional wires 21, and at least one edge of the at least two of the first functional wires 21 is provided with a space gap 20 for repairing the at least one of the second functional wires 51, and an orthographic projection of the at least one of the second functional wires 51, and an orthographic projection of the at least one of the second functional wires 51 on the first metal layer 2 covers the space gap 20 (as shown in FIG. 3).

In this embodiment, the first functional wires 21 are common electrode wires, and the second functional wires 51 are voltage dividing electrode wires. The voltage dividing electrode wires and the common electrode wires have an overlap portion, wherein an orthographic projection of the overlap portion on the first metal layer 2 covers the space gap 20, and the space gap 20 is provided at the edges of the two first functional wires 21 in the first metal layer 2, wherein the two space gaps 20 are provided at respective edges (as shown in FIG. 4), and the space gap 20 is reserved for repairing the subsequent second functional wires 51.

At the same time, the space gap 20 is defined so that the insulating layer 3 can cover the first metal layer 2, so that completely insulating the first metal layer 2 from other conductive layers, for example, the first functional wires 21 of the first metal layer 2 and the second functional wires 51 of the second metal layer 5 are completely insulated to avoid short circuiting between the first functional wires 21 of the first metal layer 2 and the second functional wires 51 of the second metal layer 5.

The pixel structure described in this embodiment may also include film layers such as a passivation layer and a flat layer, which may cover the second metal layer 5 to smooth the surface of the film layer.

The pixel definition layer 6 is arranged above the passivation layer and/or the flat layer to define the size of the light-emitting layer. The light-emitting layer can be arranged in a through hole opened on the pixel definition layer 6 to obtain a circuit structure of the pixel structure wherein the pixel structure can emit light after the circuit structure being driven.

The pixel electrode 7 is arranged in the through hole of the pixel definition layer 6 and is arranged above the light-emitting layer. The pixel electrode 7 also provides circuit support for the light-emitting of the light-emitting layer.

The technical effect of the pixel structure in this embodiment is that the space gap is defined at the edge the two first functional wires 21 of the first metal layer 2 which is crossed by the second functional wires 51 of the second metal layer 5, wherein the space gap 20 provides space for repairing the second functional wires 51, to prevent a short circuit between the first metal layer 2 and the second metal layer 5 during the repairing process, and to ensure the circuit of the pixel structure is unblocked

As shown in FIG. 5, this embodiment also provides a method of manufacturing the pixel structure, including steps S1 to S5.

S1: providing a base layer, wherein the base layer 1 is a base substrate, which providing good supporting ability and generally a glass substrate.

S2: providing a first metal layer 2 on an upper surface of the base layer 1. Specifically, a layer of metal material is coated on the upper surface of the base layer 1, and the metal material is patterned to form a plurality of first functional wires 21 spaced apart from each other, obtaining the first metal layer 2.

S3: performing a digging process on the first metal layer 2 to form a plurality of space gaps 20. The space gap 20 is defined at the edge of at least two first functional wires 21 (as shown in FIG. 2), wherein the two space gaps 20 at the edge of the two first functional wires 21 can be oppositely defined (as shown in FIG. 4).

S4: providing an insulating layer 3 on an upper surface of the first metal layer 2 and in the space gap 20. Specifically, the upper surface of the first metal layer 2 and the space gap 20 are coated with a layer of insulating material. The insulating material is an inorganic material, and the inorganic material includes silicon oxide, silicon nitride, or a multilayer film structure, which has good insulating properties.

S5: providing the second metal layer 5 on an upper surface of the insulating layer 3. Specifically, coating a layer of semiconductor material on the upper surface of the insulating layer 3, and after the patterning process, forming a plurality of second functional wires 51 spaced apart from each other, wherein at least one of the second functional wires 51 crosses at least two of the first functional wires 21, and an orthographic projection of the at least one of the second functional wires 51 on the first metal layer 2 covers the space gap 20.

In this embodiment, the first functional wires 21 are common electrode wires, and the second functional wires 51 are voltage dividing electrode wires. The overlap portion of the voltage dividing electrode wires and the common electrode wires is a space gap 20, and the space gap 20 is defined at the edge of the two first functional wires 21 in the first metal layer 2, and the two space gaps 20 are arranged respectively (as shown in FIG. 4), and the space gap 20 is provided to reserve space for repairing the subsequent second functional wires 51.

The technical effect of the manufacturing method of the pixel structure of this embodiment is that the space gap 20 is defined at the two first functional wires 21 of the first metal layer 2, and the space gap 20 provides space for repairing the second functional wires 51 of the second functional layer 5 to prevent a short circuit between the first metal layer 2 and the second metal layer 5 during the repairing process, and to ensure that the circuit of the pixel structure is unblocked.

In the above-mentioned embodiments, the description of each embodiment has its own focus. For parts that are not described in detail in one embodiment, reference may be made to related descriptions of other embodiments.

The above describes in detail a pixel structure, a manufacturing method thereof, and a display device provided by the embodiments of the present disclosure. Specific examples are used in this article to illustrate the principles and implementations of the present disclosure. The description of the above embodiments is only for help to understand the technical solutions of the present disclosure and its core ideas; those of ordinary skill in the art should understand that they can still modify the technical solutions described in the foregoing embodiments, or equivalently replace some of the technical features; and these modifications or equivalently replacement do not deviate the essence of the corresponding technical solutions from the scope of the technical solutions of the embodiments of the present disclosure.

What is claimed is:

1. A pixel structure, comprising
a base layer;
a first metal layer comprising a plurality of first functional wires spaced apart from each other, wherein the first metal layer is arranged on a surface of one side of the base layer;
a second metal layer comprising a plurality of second functional wires spaced apart from each other, wherein the second metal layer is insulated from and disposed above the first metal layer, wherein at least one of the second functional wires crosses at least two of the first functional wires, at least one edge of the at least two of the first functional wires is defined with a space gap for repairing the at least one of the second functional wires, and an orthographic projection of the at least one of the second functional wires on the first metal layer covers the space gap; and
an insulating layer covering each of the first functional wires and filling the space gaps.

2. The pixel structure according to claim 1, wherein one of the second functional wires crosses adjacent two of the first functional wires, and the space gaps are provided at respective edges of the adjacent two of the first functional wires.

3. The pixel structure according to claim 2, wherein the second functional wires are voltage dividing electrode wires, and the first functional wires are common electrode wires.

4. The pixel structure according to claim 1, wherein one of the second functional wires crosses adjacent two of the first functional wires, and the space gap is defined on an edge of one of the adjacent two of the first functional wires.

5. The pixel structure according to claim 4, wherein the second functional wires are source wires and drain wires, and the first functional wires are gate wires.

6. The pixel structure according to claim 5, further comprising:
an active layer provided on a surface of a side of the insulating layer away from the first metal layer;
a passivation layer provided on a surface of a side of the second metal layer away from the insulating layer; and
a pixel definition layer provided on a surface of a side of the passivation layer away from the second metal layer.

7. A method of manufacturing a pixel structure, comprising steps of:
providing a base layer;
providing a first metal layer on an upper surface of the base layer, wherein the first metal layer comprises a plurality of first functional wires spaced apart from each other;
providing a space gap on at least one edge of the first functional wires;
providing an insulating layer on an upper surface of the first metal layer and in the space gap; and
providing a second metal layer on an upper surface of the insulating layer, wherein the second metal layer comprises a plurality of second functional wires spaced apart from each other, at least one of the second functional wires crosses at least two of the first functional wires, and an orthographic projection of the at least one of the second functional wires on the first metal layer covers the space gap.

8. The method of manufacturing the pixel structure according to claim 7, wherein the step of providing the second metal layer on the upper surface of the insulating layer comprises:
coating a layer of metal material on the upper surface of the insulating layer, and patterning the metal material to form the plurality of second functional wires, wherein the plurality of second functional wires comprise a source wire and a drain wire;
the plurality of first functional wires comprise a gate wire; and
an orthographic projection of the drain wire on the first metal layer covers the space gap.

9. The method of manufacturing the pixel structure according to claim 7, wherein the step of providing the second metal layer on the upper surface of the insulating layer comprises:
coating a layer of metal material on the upper surface of the insulating layer, and patterning the metal material to form the plurality of second functional wires, wherein
the plurality of second functional wires comprise a voltage dividing electrode wire;
the plurality of second functional wires comprise a common electrode wire; and
the space gap is defined corresponding to an orthographic projection of the voltage dividing electrode wire on the common electrode wire.

10. A display device comprising the pixel structure according to claim 1.
